(19) United States
(12) Patent Application Publication
(10) Pub. No.: US 2013/0014386 A1
(43) Pub. Date: Jan. 17, 2013

(54) MOUNTING APPARATUS, COATING APPARATUS, MOUNTING METHOD, COATING METHOD, AND PROGRAM

(71) Applicants: Hiroshi Baba, Saitama (JP); Kenichi Oowada, Saitama (JP)

(72) Inventors: Hiroshi Baba, Saitama (JP); Kenichi Oowada, Saitama (JP)

(73) Assignee: SONY CORPORATION, Tokyo (JP)

(21) Appl. No.: 13/543,795

(22) Filed: Jul. 7, 2012

(30) Foreign Application Priority Data
Jul. 15, 2011 (JP) 2011-156438

(51) Int. Cl. H05K 3/30; B05C 11/00; B05D 5/12; H05K 13/04

(52) U.S. Cl. 29/832; 29/741; 118/500; 118/696; 427/58

(57) ABSTRACT

A mounting apparatus including: a holding portion capable of holding and releasing an electronic component including a plurality of electrodes; a movement mechanism configured to move the holding portion; a coating portion in which a coating object to be applied onto the plurality of electrodes is set; and a controller configured to control the holding portion to hold the electronic component, control the movement mechanism to move the holding portion to a position above the coating portion, control the holding portion to release the electronic component above the coating portion so that the coating object is applied onto the electrodes, control the holding portion to hold the released electronic component again, control the movement mechanism to move the holding portion to a position above one of a substrate and another electronic component, and control the electronic component to be mounted on one of the substrate and the another electronic component.

### BACKGROUND

The present disclosure relates to a technique used in, for example, a mounting apparatus that mounts an electronic component on a substrate and additionally mounts an electronic component on the mounted electronic component.

FC (Flip Chip), CSP (Chip Size Package), PoP (Package on Package), and the like are known as a technique for mounting an electronic component on a substrate and additionally mounting the electronic component on another electronic component. In such a technique, a method of applying a solder paste, flux, or the like onto a plurality of electrodes provided on a lower surface of an electronic component and mounting the electronic component on a substrate or another electronic component is sometimes used (see, for example, Japanese Patent Application Laid-open No. 2008-78456; hereinafter referred to as Patent Document 1, and Japanese Patent Application Laid-open No. Hei 11-251729).

In the mounting apparatus disclosed in Patent Document 1, an electronic component accommodated in a tray is first taken out by a sucking nozzle of a mounting head. Then, the mounting head is moved to a position above a coating unit on which a flux film is formed and is lowered. Accordingly, the flux is applied onto a plurality of solder balls provided on a lower side of the electronic component. After the flux is applied onto the solder balls, the sucking nozzle is moved upwardly, and after that, the mounting head is moved to a position above a substrate. Then, the sucking nozzle is moved downwardly, and the electronic component is mounted on the substrate.

### SUMMARY

Incidentally, the sucking nozzle may not be kept vertical to a coating object such as a solder paste and a flux due to individual differences of the sucking nozzle, the coating unit, and the like. Assuming that, when the sucking nozzle is not vertical to a film of the coating object as described above, the sucking nozzle is lowered to apply the coating object onto the plurality of electrodes, the plurality of electrodes come into contact with the film of the coating object while the electronic component is tilted with respect to the film of the coating object, with the result that the coating object cannot be uniformly applied onto the plurality of electrodes.

In view of the circumstances as described above, there is a need for a technique with which, even when a holding portion holding an electronic component is not kept vertical to a coating object, the coating object can be uniformly applied onto a plurality of electrodes of the electronic component.

According to an embodiment of the present disclosure, there is provided a mounting apparatus including a holding portion, a movement mechanism, a coating portion, and a controller.

The holding portion is capable of holding and releasing an electronic component including a plurality of electrodes.

The movement mechanism is configured to move the holding portion.

In the coating portion, a coating object to be applied onto the plurality of electrodes is set.

The controller is configured to control the holding portion to hold the electronic component, control the movement mechanism to move the holding portion to a position above the coating portion, control the holding portion to release the electronic component above the coating portion so that the coating object is applied onto the plurality of electrodes, control the holding portion to hold the released electronic component again, control the movement mechanism to move the holding portion to a position above one of a substrate and another electronic component, and control the electronic component to be mounted on one of the substrate and the another electronic component.

In the mounting apparatus, the electronic component held by the holding portion is temporarily released from the holding portion above the coating portion. As a result, even when the holding portion is not kept vertical to the coating object, the coating object can be uniformly applied onto the plurality of electrodes of the electronic component. In addition, since the electronic component in which the coating object is uniformly applied onto the plurality of electrodes can be mounted on a substrate or another electronic component in the mounting apparatus, a mounting reliability can be improved.

In the mounting apparatus, the holding portion may be capable of holding and releasing the electronic component by a switch of a pressure.

In the mounting apparatus, the controller may set the pressure of the holding portion to be a positive pressure during one of a part and all of a period between a time the holding portion releases the electronic component and a time the holding portion holds the electronic component again.

As described above, by setting the pressure of the holding portion to be a positive pressure, a wind is blown against the electronic component from the holding portion. As a result, the electronic component is apt to become parallel to the coating object, and the coating object can be more-uniformly applied onto the plurality of electrodes.

In the mounting apparatus, the controller may control the movement mechanism to lower, after the holding portion is moved to the position above the coating portion, the holding portion to a position at which the plurality of electrodes of the electronic component come into contact with the coating object and control the holding portion to release the electronic component when the holding portion is lowered to the position.

According to an embodiment of the present disclosure, there is provided a coating apparatus including a holding portion, a movement mechanism, a coating portion, and a controller.

The holding portion is capable of holding and releasing an electronic component including a plurality of electrodes.

The movement mechanism is configured to move the holding portion.

In the coating portion, a coating object to be applied onto the plurality of electrodes is set.

The controller is configured to control the holding portion to hold the electronic component, control the movement mechanism to move the holding portion to a position above the coating portion, and control the holding portion to release the electronic component above the coating portion so that the coating object is applied onto the plurality of electrodes.

In the coating apparatus, the electronic component held by the holding portion is released therefrom above the coating portion. As a result, even when the holding portion is not kept vertical to the coating object, the coating object can be uniformly applied onto the plurality of electrodes of the electronic component.

According to an embodiment of the present disclosure, there is provided a mounting method including holding, by a holding portion, an electronic component including a plurality of electrodes.

The holding portion is moved to a position above a coating portion in which a coating object to be applied onto the plurality of electrodes is set.

By the holding portion, the electronic component is released above the coating portion so that the coating object is applied onto the plurality of electrodes.

By the holding portion, the released electronic component is held again.

The holding portion is moved to a position above one of a substrate and another electronic component.

The electronic component is mounted on one of the substrate and the another electronic component.

According to an embodiment of the present disclosure, there is provided a coating method including holding, by a holding portion, an electronic component including a plurality of electrodes.

The holding portion is moved to a position above a coating portion in which a coating object to be applied onto the plurality of electrodes is set.

By the holding portion, the electronic component is released above the coating portion so that the coating object is applied onto the plurality of electrodes.

According to an embodiment of the present disclosure, there is provided a program that causes a mounting apparatus to execute the steps of:

holding, by a holding portion, an electronic component including a plurality of electrodes;

moving the holding portion to a position above a coating portion in which a coating object to be applied onto the plurality of electrodes is set;

releasing, by the holding portion, the electronic component above the coating portion so that the coating object is applied onto the plurality of electrodes;

holding again, by the holding portion, the released electronic component;

moving the holding portion to a position above one of a substrate and another electronic component; and

mounting the electronic component on one of the substrate and the another electronic component.

According to an embodiment of the present disclosure, there is provided a program that causes a coating apparatus to execute the steps of:

holding, by a holding portion, an electronic component including a plurality of electrodes;

moving the holding portion to a position above a coating portion in which a coating object to be applied onto the plurality of electrodes is set; and

releasing, by the holding portion, the electronic component above the coating portion so that the coating object is applied onto the plurality of electrodes.

As described above, according to the embodiments of the present disclosure, a technique with which, even when the holding portion holding the electronic component is not kept vertical to the coating object, the coating object can be uniformly applied onto the plurality of electrodes of the electronic component can be provided.

These and other objects, features and advantages of the present disclosure will become more apparent in light of the following detailed description of best mode embodiments thereof, as illustrated in the accompanying drawings.

### BRIEF DESCRIPTION OF DRAWINGS

FIG. 1 is a perspective view showing a mounting apparatus (coating apparatus) according to an embodiment of the present disclosure;

FIG. 2 is a side view showing an example of an electronic component mounted by the mounting apparatus;

FIG. 3 is a bottom view of the electronic component;

FIG. 4 is a side view of a sucking nozzle;

FIG. 5 is a perspective view showing a coating portion of a solder coating unit;

FIG. 6 is a cross-sectional side view of the coating portion;

FIG. 7 is a flowchart showing processing of a controller of the mounting apparatus;

FIG. 8 are diagrams sequentially showing an operation of the mounting apparatus;

FIG. 9 are diagrams sequentially showing the operation of the mounting apparatus;

FIG. 10 is a flowchart showing processing that is carried out when a solder paste is applied onto electrodes of the electronic component;

FIG. 11 is a timing chart showing an operation of the sucking nozzle that is carried out when the solder paste is applied onto the electrodes;

FIG. 12 are enlarged side views each showing a state where the solder paste is applied onto the electrodes;

FIG. 13 is a diagram showing a coating state of the solder paste applied onto the electrodes by the mounting apparatus of this embodiment;

FIG. 14 is a diagram showing a state where the solder paste is applied onto the electrodes by a mounting apparatus according to a comparative example; and

FIG. 15 is a diagram showing a coating state of the solder paste applied onto the electrodes by the mounting apparatus according to the comparative example.

### DETAILED DESCRIPTION OF EMBODIMENTS

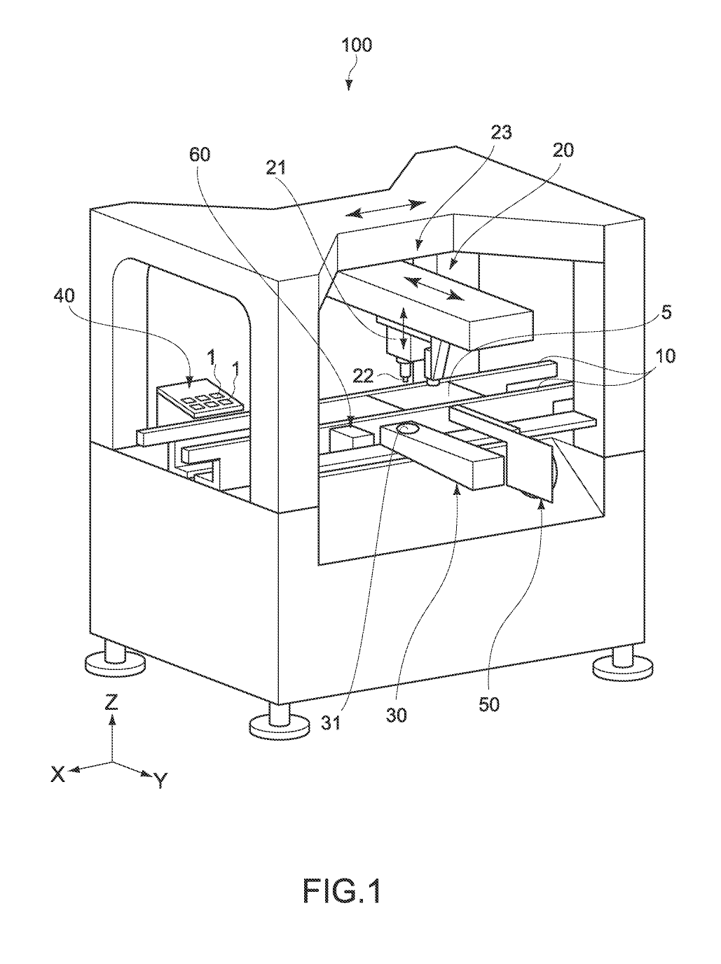

Hereinafter, an embodiment of the present disclosure will be described with reference to the drawings. FIG. 1 is a perspective view showing a mounting apparatus 100 (coating apparatus) according to an embodiment of the present disclosure. The mounting apparatus 100 is an apparatus that mounts an electronic component 1 on a substrate 5 and/or another electronic component 1 mounted on the substrate 5. The mounting apparatus 100 is used in techniques such as an FC (Flip Chip) technique, a PoP (Package on Package) technique, and a CSP (Chip Size Package) technique.

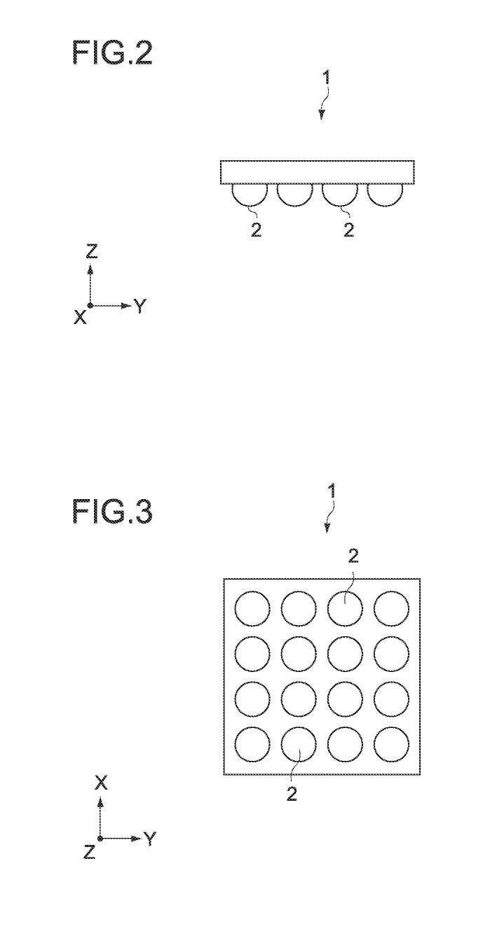

FIG. 2 is a side view showing an example of the electronic component 1 mounted by the mounting apparatus 100. FIG. 3 is a bottom view of the electronic component 1. As shown in the figures, the electronic component 1 includes a plurality of electrodes 2 on a bottom surface thereof. Examples of the electronic component 1 include a BGA (Ball Grid Array)-type electronic component 1, an LGA (Land Grid Array)-type electronic component 1, and a PGA (Pin rid Array)-type electronic component 1. Examples of those types of electronic components 1 include a processor IC (Integrated Circuit) and a memory IC.

Referring to FIG. 1, the mounting apparatus 100 includes a conveyor 10 that conveys the substrate 5 and a mounting mechanism 20 that mounts the electronic component 1 on the substrate 5, another electronic component 1, and the like. The mounting apparatus 100 also includes a solder coating unit 30 that forms a film of a solder paste 3 to be applied onto the electrodes 2, a tray 40 and part cassette 50 that accommodate the electronic component 1, and an image pickup portion 60 that picks up an image of the electronic component 1.

It should be noted that although not shown, the mounting apparatus 100 includes a controller (e.g., CPU (Central Processing Unit)) that collectively controls respective portions of the mounting apparatus 100. The mounting apparatus 100 also includes a storage portion including a nonvolatile memory that fixedly stores various programs and data requisite for processing of the controller and a volatile memory that is used as a working area of the controller. The programs may be read out from a portable recording medium such as an optical disc and a semiconductor memory.

The conveyor 10 is provided along an X-axis direction and conveys the substrate 5 mounted thereon in the X-axis direction. The conveyor 10 is driven under control of the controller and conveys the substrate 5 to a predetermined position.

The mounting mechanism 20 includes a mounting head 21 and a sucking nozzle 22 (holding portion) that is mounted on the mounting head 21 and is capable of holding and releasing (detaching) the electronic component 1. The mounting mechanism 20 also includes a head movement mechanism 23 that moves the mounting head 21 in triaxial (X, Y, and Z axes) directions. The head movement mechanism 23 uses, for example, a ball screw driving system, a belt driving system, or a linear motor driving system. It should be noted that although the mounting head 21 is moved in the Z-axis direction in this embodiment, only the sucking nozzle 22 may be moved in the Z-axis direction without moving the mounting head 21 in the Z-axis direction.

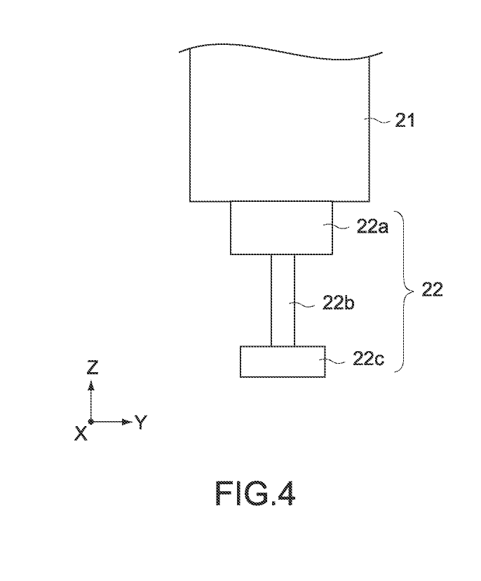

FIG. 4 is a side view of the sucking nozzle 22. The sucking nozzle 22 is connected to a pressure generation portion such as an air compressor (not shown). The sucking nozzle 22 is capable of sucking the electronic component 1 and releasing (detaching) the sucked electronic component 1 according to a switch between a negative pressure and a positive pressure (or atmosphere pressure) of the pressure generation portion.

As shown in FIG. 4, the sucking nozzle 22 includes, sequentially from an upper side, a base portion 22a attached to the mounting head 21, a nozzle portion 22b extending downwardly from the base portion 22a, and a tip end portion 22c. The tip end portion 22c of the sucking nozzle 22 is formed wider than the nozzle portion 22b. The nozzle portion 22b and the tip end portion 22c are movable in a direction vertical to the base portion 22a and are biased toward a lower side with respect to the base portion 22a by an elastic body such as a spring.

With this structure, an impact can be absorbed when the sucking nozzle 22 is lowered to take out the electronic component 1 from the tray 40 or the solder paste 3 is applied onto the electrodes 2 of the electronic component 1. It should be noted that in descriptions below, a mechanism of the sucking nozzle 22 for absorbing an impact will sometimes be referred to as damper mechanism.

Referring to FIG. 1 again, the solder coating unit 30 is detachable from the mounting apparatus 100. The solder coating unit 30 includes a coating portion 31 on which a film of the solder paste 3 is formed.

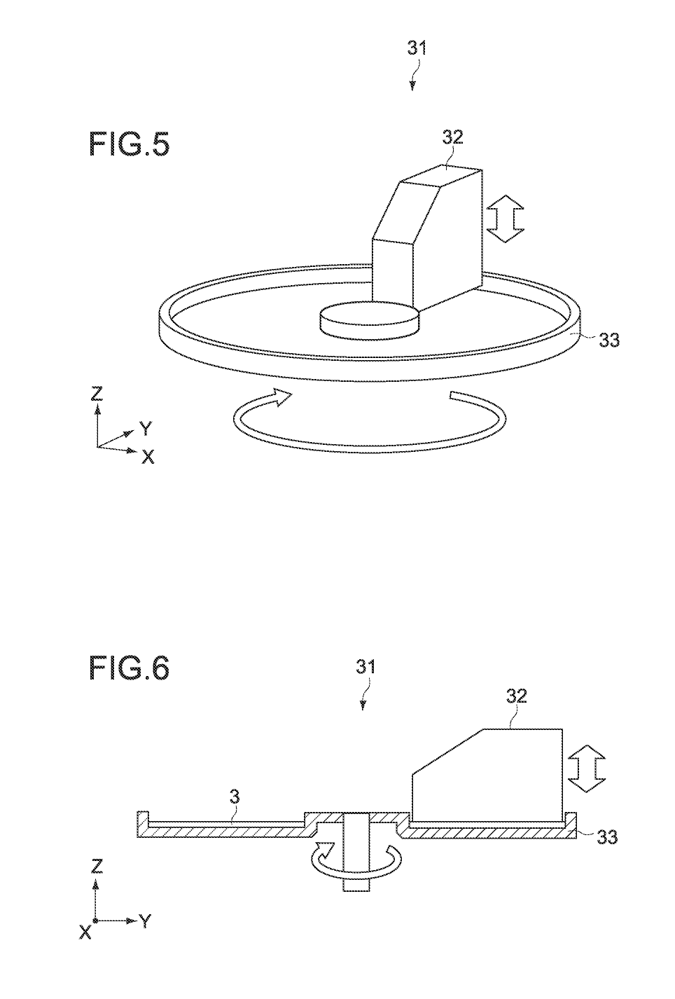

FIG. 5 is a perspective view showing the coating portion 31 of the solder coating unit 30. FIG. 6 is a cross-sectional side view of the coating portion 31. As shown in the figures, the coating portion 31 includes a squeegee 32 and a plate 33 to which the solder paste 3 is supplied so as to form the film of the solder paste 3 by the squeegee 32. The coating portion 31 also includes a squeegee movement mechanism that vertically moves the squeegee 32 and a rotation mechanism that turns the plate 33 about the Z axis.

Onto the plate 33, the solder paste 3 is supplied from a solder paste supplying apparatus (not shown). After the solder is supplied, the plate 33 is turned by the rotation mechanism. As a result, the solder paste 3 is smoothened by the squeegee 32, and the solder paste 3 having a predetermined thickness is formed on the plate 33. The thickness of the solder paste 3 can be adjusted by a vertical movement of the squeegee 32 by the squeegee movement mechanism.

The thickness of the solder paste 3 is set in relation with a height of the electrodes 2. Typically, the thickness of the solder paste 3 is set to be smaller than the height of the electrodes 2 so that, when the solder paste 3 is applied onto the electrodes 2, the solder paste 3 is not applied onto the lower surface of the electronic component 1. On the other hand, when the thickness of the solder paste 3 is too small, the solder paste 3 is insufficiently applied onto the electrodes 2. Therefore, the thickness of the solder paste 3 is typically smaller than the height of the electrodes 2 and falls within a range with which the solder can be sufficiently applied onto the electrodes 2.

Referring to FIG. 1 again, the part cassette 50 is provided on a side of the solder coating unit 30. The part cassette 50 is detachable from the mounting apparatus 100. The part cassette 50 holds a carrier tape accommodating the plurality of electronic components 1 and feeds the electronic components 1 in the carrier tape frame by frame to supply them to the mounting mechanism 20.

The tray 40 is provided on the other side of the solder coating unit 30 and the part cassette 50 with the conveyor 10 being interposed therebetween. The tray 40 accommodates the electronic components 1 arranged longitudinally and laterally. The tray 40 is also detachable from the mounting apparatus 100.

Between the conveyor 10 and the solder coating unit 30, the image pickup portion 60 that picks up an image of the electronic component 1 held by the sucking nozzle 22 is provided for checking a sucking position of the electronic component 1 sucked by the sucking nozzle 22, and the like. In the example shown in FIG. 1, the image pickup portion 60 is provided below the sucking nozzle 22. However, the position of the image pickup portion 60 is not limited, and the image pickup portion 60 may be located at substantially the same height as the sucking nozzle 22 or at a higher position than the sucking nozzle 22. In this case, an image of the electronic component 1 can be taken using a reflection of a mirror and the like.

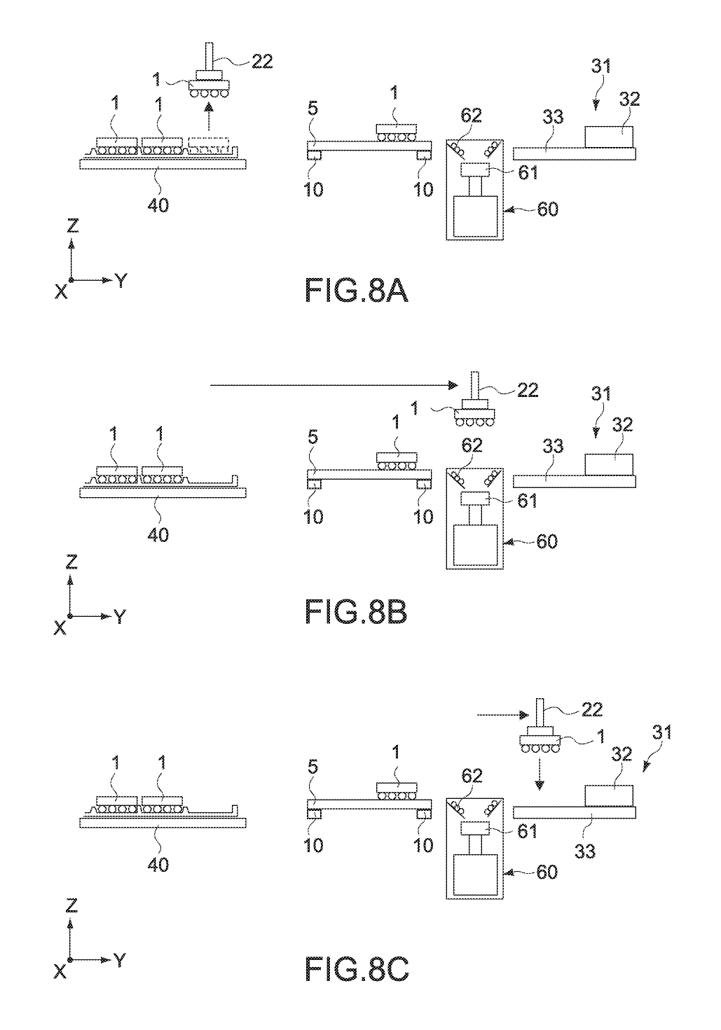

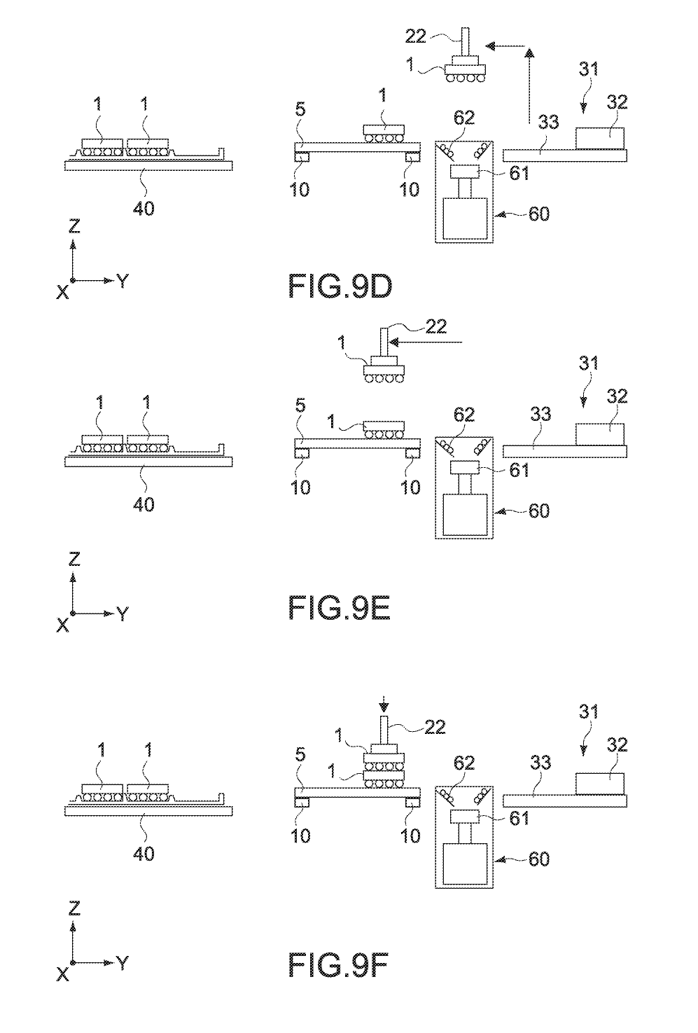

The image pickup portion 60 includes an image pickup device 61 (see FIGS. 8 and 9) such as a CCD (Charge Coupled Device) sensor and a CMOS (Complementary Metal Oxide Semiconductor) sensor. The image pickup portion 60 also includes an illumination 62 (see FIGS. 8 and 9) that illuminates the electronic component 1.

[Explanation of Operation]

Next, an operation of the mounting apparatus 100 will be described.

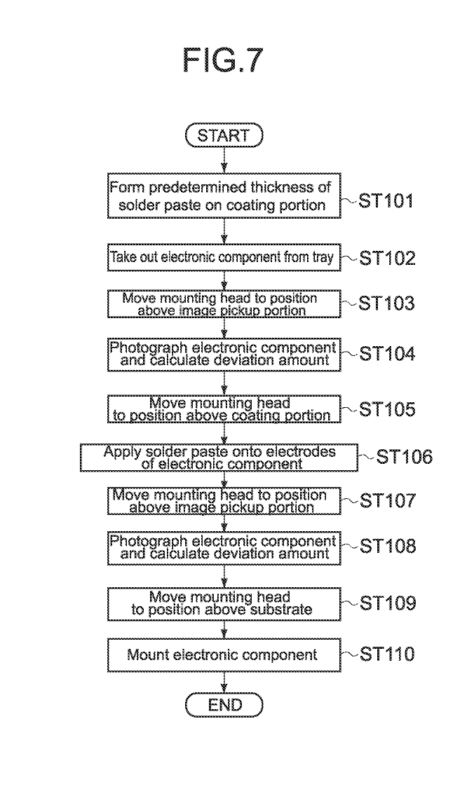

FIG. 7 is a flowchart showing processing of the controller of the mounting apparatus 100. FIGS. 8 and 9 are diagrams sequentially showing the operation of the mounting apparatus 100.

It should be noted that, assuming that the electronic components 1 are already mounted on the substrate 5 as shown in FIGS. 8 and 9, the descriptions herein will be given on processing carried out when mounting another electronic component 1 on the electronic components 1. It should be noted that in the specification, the electronic component 1 mounted at the bottom on the substrate 5 will sometimes be referred to as parent component. Further, the electronic component 1 mounted on the parent component and the electronic component 1 mounted on the electronic component 1 already mounted on the parent component will sometimes be referred to as child component.

First, the controller forms a predetermined thickness of the solder paste 3 on the coating portion 31 of the solder coating unit 30 (Step 101). At this time, the controller first acquires information on a type of the electronic component 1 to be mounted from the storage portion. Then, the controller controls the squeegee movement mechanism based on the type of the electronic component 1 and adjusts a height position of the squeegee 32. A relationship between the type of the electronic component 1 and the height (thickness) of the squeegee 32 is stored as a table in the storage portion in advance.

Next, the controller controls the rotation mechanism to turn the plate 33. Accordingly, the solder paste 3 is smoothened by the squeegee 32, and thus a predetermined thickness of the solder paste 3 is formed on the plate 33. The thickness of the solder paste 3 is set as appropriate based on the relationship with the height of the electrodes 2 of the electronic component 1 as described above.

After the predetermined thickness of the solder paste 3 is formed on the coating portion 31, the controller next takes out the electronic component 1 from the tray 40 (Step 102) (see FIG. 8A). At this time, the controller first controls the head movement mechanism 23 to lower the mounting head 21 (sucking nozzle 22). Then, the controller controls the pressure generation portion to set the pressure of the sucking nozzle 22 to be a negative pressure. As a result, the electronic component 1 is sucked and held by the sucking nozzle 22. After the electronic component 1 is held by the sucking nozzle 22, the controller controls the head movement mechanism 23 to move the mounting head 21 (sucking nozzle 22) upwardly.

Next, the controller controls the head movement mechanism 23 to move the mounting head 21 to a position above the image pickup portion 60 (Step 103) (see FIG. 8B). Then, the controller photographs the electronic component 1 held by the sucking nozzle 22 using the image pickup portion 60 (Step 104). It should be noted that at this time, the electronic component 1 is illuminated by the illumination 62. After the electronic component 1 is photographed, the controller calculates a deviation amount of the electronic component 1 from the sucking nozzle 22 based on the acquired image.

Next, the controller controls the head movement mechanism 23 to move the mounting head 21 to a position above the coating portion 31 on which the predetermined thickness of the solder paste 3 is formed (Step 105) (see FIG. 8C). At this time, the controller moves the mounting head 21 to a position on the other side of the squeegee 32 on the plate 33 of the coating portion 31, for example. It should be noted that at this time, the controller moves the mounting head 21 to a position obtained by correcting the deviation amount of the electronic component 1 from the sucking nozzle 22.

Subsequently, the controller executes processing of applying the solder paste 3 onto the electrodes 2 of the electronic component 1 (Step 106). The processing of applying the solder paste 3 onto the electrodes 2 of the electronic component 1 will be described in detail.

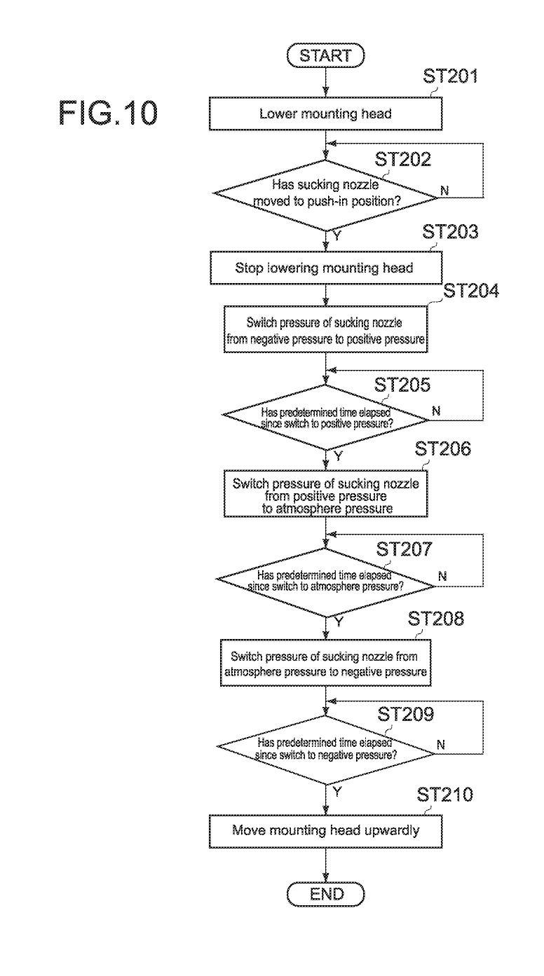

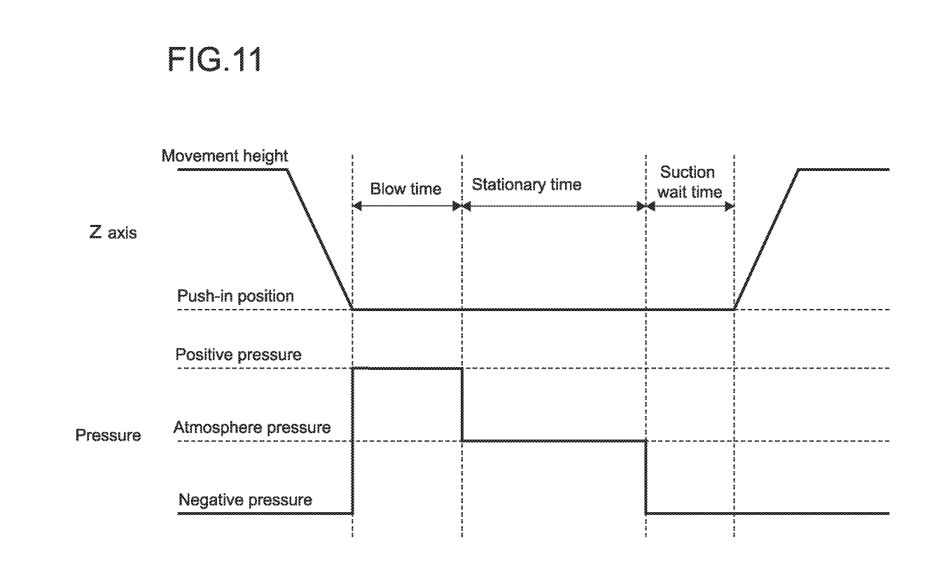

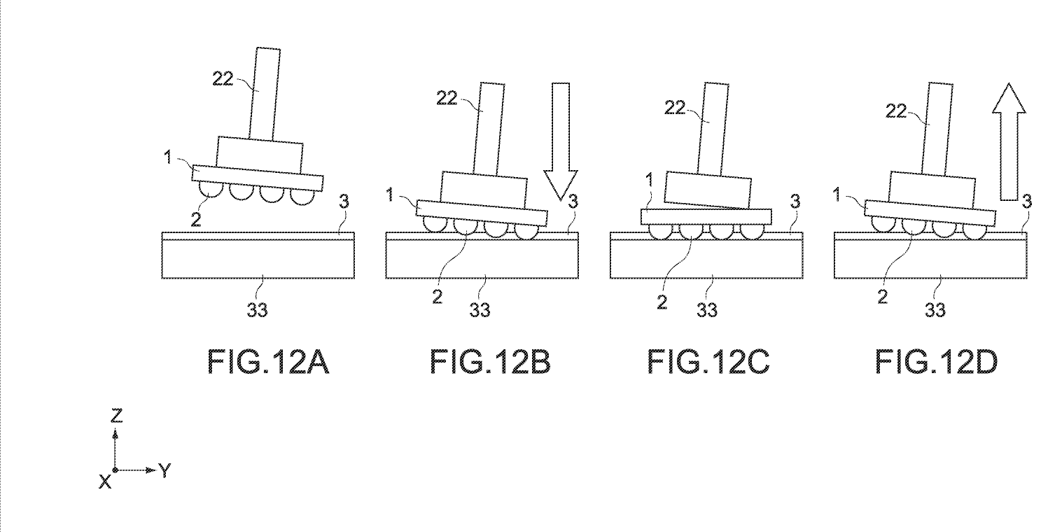

FIG. 10 is a flowchart showing the processing of applying the solder paste 3 onto the electrodes 2 of the electronic component 1. FIG. 11 is a timing chart showing an operation of the sucking nozzle 22 that is carried out when the solder paste 3 is applied onto the electrodes 2. FIG. 12 are enlarged side views each showing a state where the solder paste 3 is applied onto the electrodes 2.

It should be noted that herein, a case where the sucking nozzle 22 is not kept vertical to the film of the solder paste 3 (upper surface of plate 33) due to individual differences of the sucking nozzle 22, the solder coating unit 30, and the like as shown in FIG. 12 is assumed.

After the mounting head 21 is moved to the position above the coating portion 31, the controller first controls the head movement mechanism 23 to lower the mounting head 21 (sucking nozzle 22) (Step 201). Next, the controller judges whether the sucking nozzle 22 has moved to a push-in position (Step 202). The push-in position is a position at which the electrodes 2 of the electronic component 1 held by the sucking nozzle 22 come into contact with the upper surface of the plate 33.

After the sucking nozzle 22 moves to the push-in position (YES in Step 202), the controller stops lowering the mounting head 21 (Step 203) (see FIG. 12B).

Subsequently, the controller controls the pressure generation portion to switch the pressure of the sucking nozzle 22 from the negative pressure to a positive pressure (Step 204). As a result, the electronic component 1 is released (detached) from the sucking nozzle 22 as shown in FIG. 12C.

As described above, by releasing the electronic component 1 from the sucking nozzle 22, the electronic component 1 is apt to become parallel to the film of the solder paste 3 (upper surface of plate 33). Accordingly, the solder paste 3 can be uniformly applied onto the plurality of electrodes 2 provided on the lower surface of the electronic component 1.

After the pressure of the sucking nozzle 22 is switched from the negative pressure to the positive pressure, the controller next judges whether a predetermined time (blow time (see FIG. 11)) has elapsed since the pressure has been switched to the positive pressure (Step 205). When the predetermined time (blow time) has elapsed (YES in Step 205), the controller controls the pressure generation portion to switch the pressure of the sucking nozzle 22 from the positive pressure to an atmosphere pressure (Step 206).

Accordingly, until the predetermined time (blow time) elapses since the electronic component 1 is released from the sucking nozzle 22, wind is blown against the upper surface of the electronic component 1 from the sucking nozzle 22. As a result, the electronic component 1 is more apt to become parallel to the film of the solder paste 3 (upper surface of plate 33). Consequently, the solder paste 3 can be more-uniformly applied onto the plurality of electrodes 2. The predetermined time (blow time) is, for example, about 50 MS.

After the pressure of the sucking nozzle 22 is switched to the atmosphere pressure, the controller next judges whether a predetermined time (stationary time (see FIG. 11)) has elapsed since the pressure has been switched to the atmosphere pressure (Step 207). When the predetermined time (stationary time) has elapsed (YES in Step 207), the controller switches the pressure of the sucking nozzle 22 from the atmosphere pressure to the negative pressure (Step 208).

Accordingly, until the predetermined time (stationary time) elapses since the pressure of the sucking nozzle 22 is switched to the atmosphere pressure, the electrodes 2 are immersed in the solder paste 3. As a result, the solder paste 3 is sufficiently applied onto the plurality of electrodes 2. The predetermined time (stationary time) is, for example, about 150 ms.

After the pressure of the sucking nozzle 22 is switched from the atmosphere pressure to the negative pressure, the electronic component 1 is sucked by the sucking nozzle 22 to be held again as shown in FIG. 12D. After the pressure of the sucking nozzle 22 is switched from the atmosphere pressure to the negative pressure, the controller judges whether a predetermined time (suction wait time (see FIG. 11)) has elapsed since the pressure of the sucking nozzle 22 has been switched to the negative pressure (Step 209). The predetermined time (suction wait time) is, for example, about 50 ms.

When the predetermined time (suction wait time) has elapsed since the pressure of the sucking nozzle 22 has been switched to the negative pressure (YES in Step 209), the controller controls the head movement mechanism 23 to move the mounting head 21 upwardly (Step 210).

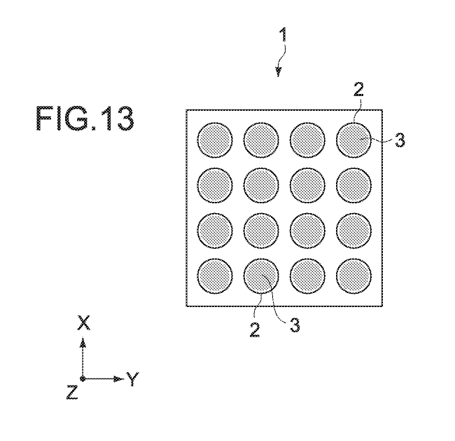

FIG. 13 is a diagram showing a coating state of the solder paste 3 applied onto the electrodes 2 by the mounting apparatus 100 of this embodiment. It can be seen from FIG. 13 that the solder paste 3 is uniformly applied onto the plurality of electrodes 2.

Here, a case where the solder paste 3 is applied onto the electrodes 2 by a mounting apparatus according to a comparative example will be described.

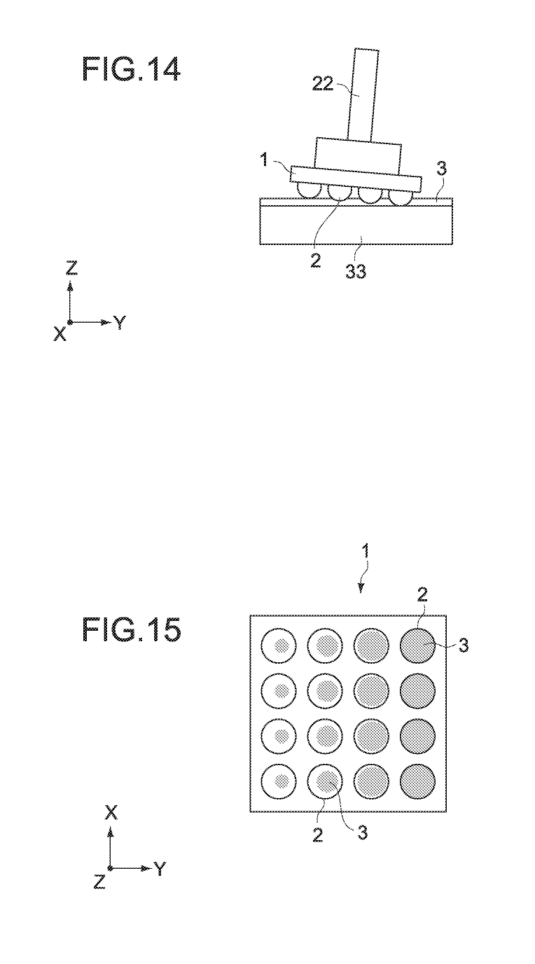

FIG. 14 is a diagram showing a state where the solder paste 3 is applied onto the electrodes 2 by the mounting apparatus according to the comparative example. FIG. 15 is a diagram showing a coating state of the solder paste 3 applied onto the electrodes 2 by the mounting apparatus according to the comparative example.

The mounting apparatus according to the comparative example does not execute the processing of temporarily releasing the electronic component 1 from the sucking nozzle 22. As shown in FIG. 14, it is assumed that the sucking nozzle 22 is lowered to apply the solder paste 3 onto the plurality of electrodes 2 of the electronic component 1.

In this case, as shown in FIG. 14, the plurality of electrodes 2 come into contact with the film of the solder paste 3 while the electronic component 1 is tilted with respect to the film of the solder paste 3. Accordingly, as shown in FIG. 15, the solder paste 3 cannot be uniformly applied onto the plurality of electrodes 2.

On the other hand, since the electronic component 1 is temporarily released from the sucking nozzle 22 as described above in this embodiment, the electronic component 1 is apt to become parallel to the film of the solder paste 3 (upper surface of plate 33). As a result, the solder paste 3 can be uniformly applied onto the plurality of electrodes 2.

Referring to FIG. 14, by strongly pressing the sucking nozzle 22 from above the electronic component 1, the electronic component 1 is released from the sucking nozzle 22 without aggressively releasing the electronic component 1 from the sucking nozzle 22. However, when the sucking nozzle 22 has a damper function for absorbing an impact, the sucking nozzle 22 is moved upwardly for absorbing an impact at a time the electrodes 2 come into contact with the upper surface of the plate 33. In this case, since the sucking nozzle 22 cannot be strongly pressed from above the electronic component 1, the electronic component 1 is not released from the sucking nozzle 22.

Further, even when the electronic component 1 can be strongly pressed, there is a fear that the electronic component 1 will be damaged when it is strongly pressed. On the other hand, according to the present disclosure, the electronic component 1 is not damaged.

Referring again to FIGS. 7 to 10, after the solder paste 3 is applied onto the electrodes 2 of the electronic component 1, the controller next controls the head movement mechanism 23 to move the mounting head 21 to a position above the image pickup portion 60 (Step 107) (see FIG. 9D). Then, the controller controls the image pickup portion 60 to photograph the electronic component 1 held by the sucking nozzle 22 (Step 108). After the electronic component 1 is photographed, the controller calculates a deviation amount of the electronic component 1 from the sucking nozzle 22 based on the acquired image.

Subsequently, the controller controls the head movement mechanism 23 to move the mounting head 21 to a position above the substrate 5 (Step 109) (see FIG. 9E). At this time, the controller moves the mounting head 21 to a position above the electronic component 1 (parent component) mounted on the substrate 5. It should be noted that the controller moves the mounting head 21 to a position obtained by correcting the deviation amount of the electronic component 1 from the sucking nozzle 22.

After the mounting head 21 is moved to the position above the electronic component 1 (parent component) on the substrate 5, the controller mounts an electronic component 1 (child component) on the electronic component 1 (parent component) on the substrate 5 (Step 110) (see FIG. 9F). At this time, since the solder paste 3 is uniformly applied onto the plurality of electrodes 2 of the electronic component 1 as described above, a mounting reliability can be improved.

[Various Modified Examples]

In the example described above, the BGA-, LGA-, or PGA-type electronic component 1 in which the electrodes 2 are formed on the lower side thereof has been taken as an example of the electronic component 1 to be mounted. However, the electronic component 1 to be mounted is not limited thereto and may be, for example, a resistor, a capacitor, or a coil.

The descriptions above have been given on the case where the electronic component 1 is taken out of the tray 40. However, the electronic component 1 may be taken out of the part cassette 50.

The descriptions above have been given on the case where the electronic component 1 (child component) is mounted on the electronic component 1 (parent component) already mounted at the bottom of the substrate 5. However, the present disclosure is not limited thereto and is also applicable to a case where the electronic component 1 is mounted on the substrate 5 or the electronic component 1 (child component) is mounted on the electronic component 1 (child component) already mounted on the electronic component 1 (parent component) mounted on the substrate 5.

In the example above, the solder paste 3 has been taken as an example of the coating object to be applied onto the electrodes 2. However, the coating object may instead be a flux, an adhesive, or the like.

The descriptions above have been given on the case where the pressure of the sucking nozzle 22 is set to be a positive pressure during a part of a period between a time the electronic component 1 is released from the sucking nozzle 22 and a time the electronic component 1 is held again by the sucking nozzle 22. However, the present disclosure is not limited thereto, and the pressure of the sucking nozzle 22 may be set to be a positive pressure so that wind is blown against the electronic component 1 from the sucking nozzle 22 during all of the period described above.

It should be noted that the pressure of the sucking nozzle 22 does not necessarily need to be a positive pressure. For example, the pressure of the sucking nozzle 22 may be an atmosphere pressure during the period between a time the electronic component 1 is released from the sucking nozzle 22 and a time the electronic component 1 is held again by the sucking nozzle 22. Also in such a case, the coating object can be uniformly applied onto the plurality of electrodes 2 of the electronic component 1.

In the example above, the sucking nozzle 22 has been taken as an example of a holding portion that holds and releases (detaches) the electronic component 1. However, the holding portion is not limited to the sucking nozzle 22. Other examples of the holding portion include a holding portion that holds an electronic component by an electromagnetic force and a holding portion that sandwiches an electronic component from both sides.

The present disclosure may also take the following structures.

(1) A mounting apparatus, including:

a holding portion capable of holding and releasing an electronic component including a plurality of electrodes;

a movement mechanism configured to move the holding portion;

a coating portion in which a coating object to be applied onto the plurality of electrodes is set; and

a controller configured to control the holding portion to hold the electronic component, control the movement mechanism to move the holding portion to a position above the coating portion, control the holding portion to release the electronic component above the coating portion so that the coating object is applied onto the plurality of electrodes, control the holding portion to hold the released electronic component again, control the movement mechanism to move the holding portion to a position above one of a substrate and another electronic component, and control the electronic component to be mounted on one of the substrate and the another electronic component.

(2) The mounting apparatus according to (1),

in which the holding portion is capable of holding and releasing the electronic component by a switch of a pressure.

(3) The mounting apparatus according to (2),

in which the controller sets the pressure of the holding portion to be a positive pressure during one of a part and all of a period between a time the holding portion releases the electronic component and a time the holding portion holds the electronic component again.

(4) The mounting apparatus according to any one of (1) to (3),

in which the controller controls the movement mechanism to lower, after the holding portion is moved to the position above the coating portion, the holding portion to a position at which the plurality of electrodes of the electronic component come into contact with the coating object and controls the holding portion to release the electronic component when the holding portion is lowered to the position.

(5) A coating apparatus, including:

a holding portion capable of holding and releasing an electronic component including a plurality of electrodes;

a movement mechanism configured to move the holding portion;

a coating portion in which a coating object to be applied onto the plurality of electrodes is set; and

a controller configured to control the holding portion to hold the electronic component, control the movement mechanism to move the holding portion to a position above the coating portion, and control the holding portion to release the electronic component above the coating portion so that the coating object is applied onto the plurality of electrodes.

(6) A mounting method, including:

holding, by a holding portion, an electronic component including a plurality of electrodes;

moving the holding portion to a position above a coating portion in which a coating object to be applied onto the plurality of electrodes is set;

releasing, by the holding portion, the electronic component above the coating portion so that the coating object is applied onto the plurality of electrodes;

holding again, by the holding portion, the released electronic component;

moving the holding portion to a position above one of a substrate and another electronic component; and

mounting the electronic component on one of the substrate and the another electronic component.

(7) A coating method, including:

holding, by a holding portion, an electronic component including a plurality of electrodes;

moving the holding portion to a position above a coating portion in which a coating object to be applied onto the plurality of electrodes is set; and

releasing, by the holding portion, the electronic component above the coating portion so that the coating object is applied onto the plurality of electrodes.

(8) A program that causes a mounting apparatus to execute the steps of:

holding, by a holding portion, an electronic component including a plurality of electrodes;

moving the holding portion to a position above a coating portion in which a coating object to be applied onto the plurality of electrodes is set;

releasing, by the holding portion, the electronic component above the coating portion so that the coating object is applied onto the plurality of electrodes;

holding again, by the holding portion, the released electronic component;

moving the holding portion to a position above one of a substrate and another electronic component; and

mounting the electronic component on one of the substrate and the another electronic component.

(9) A program that causes a coating apparatus to execute the steps of:

holding, by a holding portion, an electronic component including a plurality of electrodes;

moving the holding portion to a position above a coating portion in which a coating object to be applied onto the plurality of electrodes is set; and

releasing, by the holding portion, the electronic component above the coating portion so that the coating object is applied onto the plurality of electrodes.

The present disclosure contains subject matter related to that disclosed in Japanese Priority Patent Application JP 2011-156438 filed in the Japan Patent Office on Jul. 15, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A mounting apparatus, comprising:
a holding portion capable of holding and releasing an electronic component including a plurality of electrodes;
a movement mechanism configured to move the holding portion;
a coating portion in which a coating object to be applied onto the plurality of electrodes is set; and
a controller configured to control the holding portion to hold the electronic component, control the movement mechanism to move the holding portion to a position above the coating portion, control the holding portion to release the electronic component above the coating portion so that the coating object is applied onto the plurality of electrodes, control the holding portion to hold the released electronic component again, control the movement mechanism to move the holding portion to a position above one of a substrate and another electronic component, and control the electronic component to be mounted on one of the substrate and the another electronic component.

2. The mounting apparatus according to claim 1,
wherein the holding portion is capable of holding and releasing the electronic component by a switch of a pressure.

3. The mounting apparatus according to claim 2,
wherein the controller sets the pressure of the holding portion to be a positive pressure during one of a part and all of a period between a time the holding portion releases the electronic component and a time the holding portion holds the electronic component again.

4. The mounting apparatus according to claim 1,
wherein the controller controls the movement mechanism to lower, after the holding portion is moved to the position above the coating portion, the holding portion to a position at which the plurality of electrodes of the electronic component come into contact with the coating object and controls the holding portion to release the electronic component when the holding portion is lowered to the position.

5. A coating apparatus, comprising:
a holding portion capable of holding and releasing an electronic component including a plurality of electrodes;
a movement mechanism configured to move the holding portion;
a coating portion in which a coating object to be applied onto the plurality of electrodes is set; and
a controller configured to control the holding portion to hold the electronic component, control the movement mechanism to move the holding portion to a position above the coating portion, and control the holding portion to release the electronic component above the coating portion so that the coating object is applied onto the plurality of electrodes.

6. A mounting method, comprising:
holding, by a holding portion, an electronic component including a plurality of electrodes;
moving the holding portion to a position above a coating portion in which a coating object to be applied onto the plurality of electrodes is set;
releasing, by the holding portion, the electronic component above the coating portion so that the coating object is applied onto the plurality of electrodes;
holding again, by the holding portion, the released electronic component;
moving the holding portion to a position above one of a substrate and another electronic component; and
mounting the electronic component on one of the substrate and the another electronic component.

7. A coating method, comprising:
holding, by a holding portion, an electronic component including a plurality of electrodes;
moving the holding portion to a position above a coating portion in which a coating object to be applied onto the plurality of electrodes is set; and
releasing, by the holding portion, the electronic component above the coating portion so that the coating object is applied onto the plurality of electrodes.

8. A program that causes a mounting apparatus to execute the steps of:
holding, by a holding portion, an electronic component including a plurality of electrodes;
moving the holding portion to a position above a coating portion in which a coating object to be applied onto the plurality of electrodes is set;
releasing, by the holding portion, the electronic component above the coating portion so that the coating object is applied onto the plurality of electrodes;
holding again, by the holding portion, the released electronic component;
moving the holding portion to a position above one of a substrate and another electronic component; and
mounting the electronic component on one of the substrate and the another electronic component.

9. A program that causes a coating apparatus to execute the steps of:
holding, by a holding portion, an electronic component including a plurality of electrodes;
moving the holding portion to a position above a coating portion in which a coating object to be applied onto the plurality of electrodes is set; and
releasing, by the holding portion, the electronic component above the coating portion so that the coating object is applied onto the plurality of electrodes.
